(19) United States
(12) Patent Application Publication
(10) Pub. No.: US 2025/0087593 A1
(43) Pub. Date: Mar. 13, 2025

(54) SEMICONDUCTOR PACKAGE

(71) Applicant: Samsung Electronics Co., Ltd., Suwon-si (KR)

(72) Inventors: Juil CHOI, Suwon-si (KR); Jusuk KANG, Suwon-si (KR); Jongho PARK, Suwon-si (KR); Jaeyoung LEE, Suwon-si (KR); Hyunju LEE, Suwon-si (KR); Wonho CHOI, Suwon-si (KR)

(73) Assignee: Samsung Electronics Co., Ltd., Suwon-si (KR)

(21) Appl. No.: 18/581,596

(22) Filed: Feb. 20, 2024

(30) Foreign Application Priority Data
Sep. 11, 2023 (KR) 10-2023-0120095

(51) Int. Cl. H01L 23/544; H01L 23/00; H01L 23/48

(52) U.S. Cl. CPC H01L 23/544; H01L 23/481; H01L 24/08; H01L 2223/54426; H01L 2224/08145

(57) ABSTRACT

A semiconductor package including a first semiconductor chip including a substrate having a front surface and a rear surface opposite to each other, front pads on the front surface, through-electrodes electrically connected to the front pads, passing through the substrate, and protruding onto the rear surface, and rear pads on the through-electrodes, a first dielectric layer covering at least a portion of the first semiconductor chip, the first dielectric layer surrounding, on the rear surface of the substrate, a portion of a side surface of each of the through-electrodes and a side surface of each of the rear pads, on the rear surface of the substrate, at least one first alignment structure within the first dielectric layer around the first semiconductor chip, and a second semiconductor chip on the first dielectric layer may be provided.

### CROSS-REFERENCE TO RELATED APPLICATION(S)

This application claims benefit of priority to Korean Patent Application No. 10-2023-0120095filed on Sep. 11, 2023 in the Korean Intellectual Property Office, the disclosure of which is incorporated herein by reference in its entirety.

### BACKGROUND

The present inventive concepts relate to semiconductor packages.

With the implementation of high performance and miniaturization of electronic products, there is a growing need for semiconductor packages in which heterogeneous semiconductor chips are integrated into a single semiconductor chip. Accordingly, technology has been developed to vertically stack semiconductor chips, electrically connected to each other via a through-silicon via (TSV).

### SUMMARY

Some example embodiments of the present inventive concepts provide semiconductor packages having a simplified process.

According to an example embodiment of the present inventive concepts, a semiconductor package may include a first semiconductor chip including a substrate having front and rear surfaces opposite to each other, front pads on the front surface, through-electrodes electrically connected to the front pads, passing through the substrate, and protruding onto the rear surface, and rear pads on the through-electrodes, a first dielectric layer covering at least a portion of the first semiconductor chip, the first dielectric layer surrounding, on the rear surface of the substrate, a portion of a side surface of each of the through-electrodes and a side surface of each of the rear pads, on the rear surface of the substrate, at least one first alignment structure within the first dielectric layer and around the first semiconductor chip, a second semiconductor chip on the first dielectric layer, the second semiconductor chip including connection pads in contact with the rear pads, and an insulating layer surrounding the connection pads and being in contact with the first dielectric layer, a second dielectric layer covering at least a portion of the second semiconductor chip, the second dielectric layer in contact with the first dielectric layer, at least one second alignment structure within the second dielectric layer around the second semiconductor chip, a dummy chip on the second dielectric layer, and bump structures on the front pads of the first semiconductor chip.

According to an example embodiment of the present inventive concepts, a semiconductor package may include a first semiconductor chip including front pads, rear pads opposite to the front pads, and through-electrodes electrically connecting the front pads and the rear pads to each other, at least one alignment structure around the first semiconductor chip, a lower dielectric layer surrounding a side surface of the at least one alignment structure and a side surface of the first semiconductor chip, an upper dielectric layer on the lower dielectric layer and surrounding a side surface of each of the rear pads, and a second semiconductor chip on the upper dielectric layer, the second semiconductor chip including connection pads in contact with the rear pads, and an insulating layer surrounding the connection pads and being in contact with the upper dielectric layer.

According to an example embodiment of the present inventive concepts, a semiconductor package may include a first semiconductor chip including a substrate having front and rear surfaces opposite to each other, front pads on the front surface, through-electrodes electrically connected to the front pads and extending onto the rear surface, and rear pads on the through-electrodes, at least one alignment structure around the first semiconductor chip, a first dielectric layer covering the rear surface and a side surface of the substrate, a portion of a side surface of each of the through-electrodes, a side surface of each of the rear pads, and a side surface and an upper end of the at least one alignment structure, a second semiconductor chip on the first dielectric layer, the second semiconductor chip including connection pads in contact with the rear pads, and an insulating layer surrounding the connection pads and being in contact with the first dielectric layer, a second dielectric layer covering an upper surface and a side surface of the second semiconductor chip, and a dummy chip on the second dielectric layer. The at least one alignment structure may be electrically insulated from the first semiconductor chip, the second semiconductor chip, and the dummy chip.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1A is a cross-sectional view of a semiconductor package according to an example embodiment, and FIG. 1B is a plan view taken along line I-I′ of FIG. 1A;

FIG. 2 is a cross-sectional view of a semiconductor package according to an example embodiment;

FIG. 3 is a cross-sectional view of a semiconductor package according to an example embodiment;

FIG. 4 is a cross-sectional view of a semiconductor package according to an example embodiment;

FIG. 5A is a cross-sectional view of a semiconductor package according to an example embodiment, and FIG. 5B is a plan view taken along line II-II′ of FIG. 5A;

FIG. 6 is a cross-sectional view of a semiconductor package according to an example embodiment;

FIG. 7 is a cross-sectional view of a semiconductor package according to an example embodiment;

FIG. 8A is a plan view of a semiconductor package according to an example embodiment, and FIG. 8B is a cross-sectional view taken along line III-III′ of FIG. 8A; and

FIGS. 9A to 9K are diagrams illustrating a process of manufacturing a semiconductor package according to an example embodiment.

### DETAILED DESCRIPTION

Hereinafter, some example embodiments will be described in detail. Unless otherwise described, the terms such as “upper,” “upper portion,” “upper surface,” “lower,” “lower portion,” “lower surface,” and “side surface” are based on the drawings, and may vary depending on a direction in which an element or component is actually arranged.

In addition, ordinal numbers such as “first,” “second,” “third,” and the like may be used as labels for specific elements, operations, directions, and the like, to distinguish various elements, steps, directions, and the like from one another. A term, not described in the specification using “first,” “second,” and the like, may still be referred to as “first” or “second” in the claims. In addition, a term referenced by a particular ordinal number (for example, “first” in a particular claim) may be described elsewhere with a different ordinal number (for example, “second” in the specification or another claim).

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

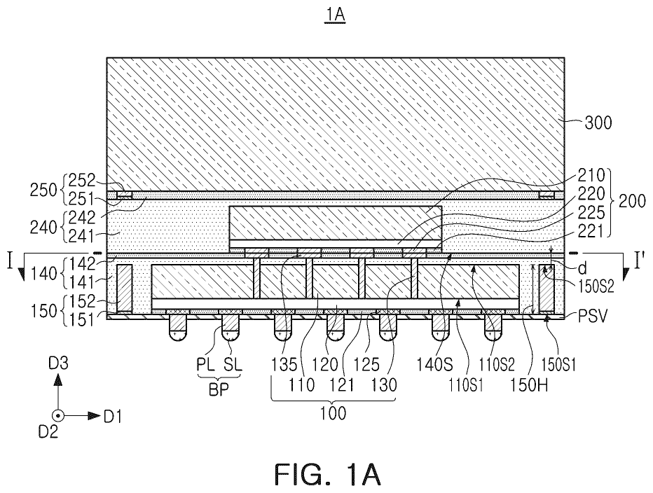

FIG. 1A is a cross-sectional view of a semiconductor package according to an example embodiment, and FIG. 1B is a plan view taken along line I-I′ of FIG. 1A.

Referring to FIGS. 1A and 1B, a semiconductor package 1A according to an example embodiment may include a first semiconductor chip 100, a first dielectric layer 140, at least one first alignment structure 150, and a second semiconductor chip 200. The semiconductor package 1A may further include a second dielectric layer 240.

The first semiconductor chip 100 and the second semiconductor chip 200 may include a logic chip including a central processor (CPU), a graphics processor (GPU), a field programmable gate array (FPGA), a digital signal processor (DSP), an encryption processor, a microprocessor, microcontrollers, an analog-to-digital converter, and the like, and a memory chip including a volatile memory (e.g., Dynamic Random Access Memory (DRAM) and Static Random Access Memory (SRAM)), and/or a non-volatile memory (e.g., Phase-change Random Access Memory (PRAM), Magnetoresistive Random Access Memory (MRAM), Ferroelectric Random Access Memory (FeRAM), Resistive Random Access Memory (RRAM), and flash memory).

The number of second semiconductor chips 200, stacked on the first semiconductor chip 100 in a vertical or horizontal direction, may be two or more. For example, the first semiconductor chip 100 may include a logic chip such as an application-specific semiconductor (ASIC), and the second semiconductor chip 200 may include a memory providing cache information to the first semiconductor chip 100. A size of the second semiconductor chip 200 may be smaller than a size of the first semiconductor chip 100. For example, a planar area of the second semiconductor chip 200 may be smaller than a planar area of the first semiconductor chip 100. In some example embodiments, the size of the second semiconductor chip 200 may be larger than the size of the first semiconductor chip 100.

The first semiconductor chip 100 may include a first substrate 110, a first circuit layer 120, a first insulating layer 121, front pads 125, through-electrodes 130, and rear pads 135.

The first substrate 110 may have a front surface 110S1 and a rear surface 110S2 opposite to the front surface 110S1. The first substrate 110 may be a semiconductor wafer including semiconductor elements such as silicon and germanium, or compound semiconductors such as silicon carbide (SiC), gallium arsenide (GaAs), indium arsenide (InAs), and indium phosphide (InP). A front surface 110S1 of the first substrate 110 may be an active surface (e.g., the surface facing the first circuit layer 120) having an active region doped with impurities, and a rear surface 110S2 of the first substrate 110 may be an inactive surface having no active region.

The first circuit layer 120 may be disposed on the front surface 110S1 of the first substrate 110. The first circuit layer 120 may include an integrated circuit including individual elements (not illustrated) formed on the front surface 110S1 of the first substrate 110, and an interconnection structure (not illustrated) electrically connecting the individual elements (not illustrated) to the front pads 125. The “individual devices” may include a field effect transistor (FET) device such as a planar FET or FinFET, a memory device such as flash memory, DRAM, SRAM, EEPROM, PRAM, MRAM, FeRAM, or RRAM, a logic device such as AND, OR, or NOT, and various active devices and/or passive devices such as logic devices, a system LSI, CIS, and MEMS. The “interconnection structure” may be formed to have a multilayer structure including an interconnection pattern and a via formed of, for example, aluminum (Al), gold (Au), cobalt (Co), copper (Cu), nickel (Ni), lead (Pb), tantalum (Ta), tellurium (Te), titanium (Ti), tungsten (W), or combinations thereof. The first circuit layer 120 may further include an interlayer insulating layer (not illustrated) covering the “individual elements” and the “interconnection structure.” The “interlayer insulating layer” may include flowable oxide (FOX), tonen silazene (TOSZ), undoped silica glass (USG), borosilica glass (BSG), phosphosilica glass (PSG), borophosphosilica glass (BPSG), plasma enhanced tetra ethyl ortho silicate (PETEOS), fluoride silicate glass (FSG), high density plasma (HDP) oxide, plasma enhanced oxide (PEOX), flowable CVD (FCVD) oxide, or combinations thereof.

The first insulating layer 121 may be disposed below the first circuit layer 120 and may be formed to surround the front pads 125. For example, the first insulating layer 121 may include at least one of silicon oxide (SiO), silicon nitride (SiN), or silicon carbonitride (SiCN).

The front pads 125 may be connection terminals electrically connected to the integrated circuit of the first circuit layer 120. The front pads 125 may include one of copper (Cu), nickel (Ni), titanium (Ti), aluminum (Al), gold (Au), and silver (Ag), or alloys thereof. The front pads 125 may be connection terminals of a bare chip (e.g., aluminum pads), but the present inventive concepts are not limited thereto. In some example embodiments, the front pads 125 may be connection structures (e.g., copper pads) formed on the connection terminals of the bare chip. A barrier layer (not illustrated) including at least one of titanium (Ti), titanium nitride (TiN), tantalum (Ta), or tantalum nitride (TaN) may be formed between the front pads 125 and the first insulating layer 121.

The through-electrodes 130 may electrically connect the front pads 125 and the rear pads 135 to each other. The through-electrodes 130 may be electrically connected to the front pads 125, and may extend onto the rear surface 110S2 of the substrate 110. The through-electrodes 130 may pass through the substrate 110 and protrude to the rear surface 110S2. The through-electrodes 130 may include a via plug and a side barrier film surrounding a side surface of the via plug. The “via plug” may include, for example, tungsten (W), titanium (Ti), aluminum (Al), or copper (Cu), and may be formed using a plating process, PVD process, or CVD process. The “side barrier film” may include titanium (Ti), titanium nitride (TiN), tantalum (Ta), or tantalum nitride (TaN), and may be formed using a plating process, PVD process, or CVD process. A side insulating film (not illustrated) including an insulating material formed by, for example, high aspect ratio process (HARP) such as silicon oxide, silicon nitride, or silicon oxynitride, may be formed between the through-electrodes 130 and the substrate 110.

The rear pads 135 may be disposed on the through-electrodes 130, respectively. The rear pads 135 may include at least one of copper (Cu), nickel (Ni), titanium (Ti), aluminum (Al), gold (Au), silver (Ag), or alloys thereof. The rear pads 135 may be spaced apart from the substrate 110. A first dielectric layer 140 may be filled between the rear pads 135 and the rear surface 110S2 of the substrate 110.

Bump structures BP may be disposed on the front pads 125. The bump structures BP may connect the semiconductor package 1A to an external device such as a module substrate or main board. For example, the bump structures BP may have a pillar portion PL and a solder portion SL. The pillar portion PL may include copper (Cu) or an alloy of copper (Cu), and the solder portion SL may include a low melting point metal, such as tin (Sn) or an alloy including tin (Sn) (e.g., Sn—Ag or Sn—Ag—Cu). In some example embodiments, the bump structures BP may include only the pillar portion PL or only the solder portion SL.

The first dielectric layer 140 may cover at least a portion of the first semiconductor chip 100, and may surround a portion of a side surface of each of the through-electrodes 130 and a side surface of each of the rear pads 135, on the rear surface 110S2 of the substrate 110.

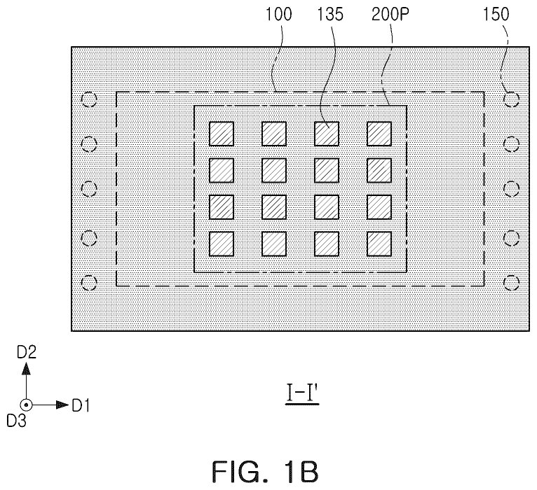

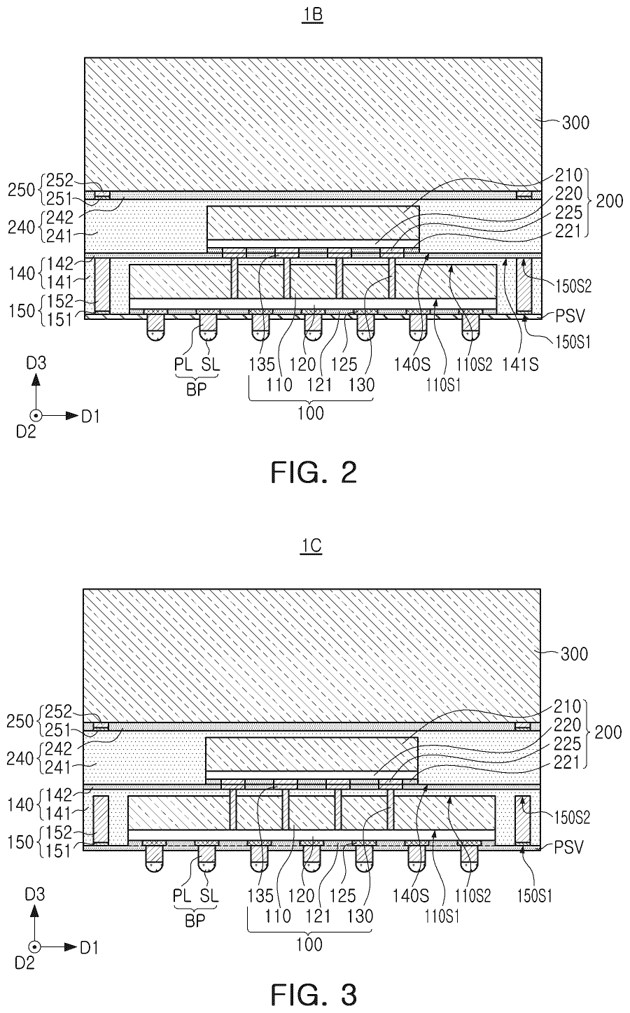

The first dielectric layer 140 may include a first lower dielectric layer 141 and a first upper dielectric layer 142. The first lower dielectric layer 141 may cover the rear surface 110S2 and a side surface of the substrate 110, a portion of a side surface of each of the through-electrodes 130 (indicating a portion protruding onto the rear surface 110S2), and a side surface and an upper end 150S2 of the alignment structure 150. In some example embodiments, the upper end 150S2 of the first alignment structure 150 may be exposed from the first lower dielectric layer 141 (see the example embodiment of FIG. 2). The upper end 150S2 of the first alignment structure 150 may be on a level the same as or lower than that of an upper surface 141S of the first lower dielectric layer 141. A lower end 150S1 of the first alignment structure 150 may be coplanar with a lower surface of the first dielectric layer 140 (or the first lower dielectric layer 141). The first upper dielectric layer 142 may be disposed on the first lower dielectric layer 141, and may cover a side surface of each of the rear pads 135. The first upper dielectric layer 142 may provide a bonding surface for bonding and coupling to the second semiconductor chip 200.

The first dielectric layer 140 may include at least one of silicon oxide (SiO), silicon nitride (SiN), or silicon carbonitride (SiCN). The first lower dielectric layer 141 and the first upper dielectric layer 142 may include the same material (e.g., silicon oxide), but the present inventive concepts are not limited thereto. The first lower dielectric layer 141 may include at least one of silicon oxide (SiO) or silicon nitride (SiN) applied to protect the through-electrodes 130 in a planarization process (e.g., a Chemical Mechanical Polishing (CMP) process). The first upper dielectric layer 142 may include a material, for example, silicon oxide (SiO) or silicon carbonitride (SiCN) that may be bonded and coupled to the second insulating layer 221 of the second semiconductor chip 200. However, the material included in the first dielectric layer 140 is not limited to the examples described above. Depending on the process, a boundary between the first upper dielectric layer 142 and the second insulating layer 221 may not be clearly identified.

At least one first alignment structure 150 may be disposed within the first dielectric layer 140 around (or adjacent to) the first semiconductor chip 100. The at least one first alignment structure 150 may be disposed on at least one side of the first semiconductor chip 100. As illustrated in FIG. 1B, the first alignment structure 150 may be disposed on both sides of the first semiconductor chip 100, but the present inventive concepts are not limited thereto. In some example embodiments, the at least one first alignment structure 150 may be disposed on only one side of the first semiconductor chip 100 or may be disposed on all sides of the first semiconductor chip 100.

The at least one first alignment structure 150 may include a first lower material layer 151 and a first upper material layer 152 on the first lower material layer 151. The first lower material layer 151 may include titanium (Ti) or a titanium (Ti) alloy, and the first upper material layer 152 may include copper (Cu) or a copper (Cu) alloy. However, a constituent material of the first alignment structure 150 may be not limited to the metal described above, and the first alignment structure 150 may include a material that may be detected by an alignment key in the process of disposing the first semiconductor chip 100 and the second semiconductor chip 200, without limitation.

According to some example embodiments, the at least one first alignment structure 150 may be an alignment key for determining a position (“200P” in FIG. 1B) of the second semiconductor chip 200. That is, the at least one first alignment structure 150 may be used as an alignment key for both the first semiconductor chip 100 and the second semiconductor chip 200, such that a process of forming an alignment key for the second semiconductor chip 200 and the bump structures BP may be omitted, and a process of manufacturing the semiconductor package may be simplified. As compared to a case in which an alignment key of the first semiconductor chip 100 and an alignment key of the second semiconductor chip 200 are provided respectively, the number of layers processed using a photo process may be reduced, thereby improving the overlay tolerance of the first semiconductor chip 100 and the second semiconductor chip 200.

The at least one first alignment structure 150 may be formed in the form of a column having a desired (or alternatively, predetermined) height in order to be detected as an alignment key by a laser or the like during an operation of attaching the second semiconductor chip 200. For example, the at least one first alignment structure 150 may be in the form of a circular column, a polygonal column, or a cross column. The at least one first alignment structure 150 may be an alignment key for the first semiconductor chip 100 and the second semiconductor chip 200 and may be electrically insulated from the first semiconductor chip 100 and the second semiconductor chip 200.

A height 150H of the at least one first alignment structure 150 may be higher than a thickness of the substrate 110. The upper end 150S2 of the at least one first alignment structure 150 may be on a level the same as or lower than that of an upper end of each of the through-electrodes 130. The upper end 150S2 of the at least one first alignment structure 150 may be at a level between the rear surface 110S2 of the substrate 110 and an upper surface 140S of the first dielectric layer 140. The lower end 150S1 of the at least one first alignment structure 150 may be on a level the same as that of each of the front pads 125.

The entire upper end 150S2 of the at least one first alignment structure 150 may be covered by the first lower dielectric layer 141 or the first upper dielectric layer 142. A gap d between the upper end 150S2 of the at least one first alignment structure 150 and the upper surface140S of the first dielectric layer 140 may be about 10 μm or less, for example, about 4 μm to about 10 μm, about 5 μm to about 10 μm, about 6 μm to about 10 μm, or the like. When the gap d between the first alignment structure 150 and the upper surface 140S of the first dielectric layer 140 is greater than about 10 μm, it may be difficult to defect the first alignment structure 150 during the operation of attaching the second semiconductor chip 200. A lower limit of the gap d between the first alignment structure 150 and the upper surface 140S of the first dielectric layer 140 may be determined by a protrusion height of each of the through-electrodes 130 and a thickness of each of the rear pads 135.

In some example embodiments, the semiconductor package 1A may further include a passivation layer PSV. The passivation layer PSV may be provided below the first dielectric layer 140 and may cover a bottom of the at least one first alignment structure 150 and surround each of the bump structures BP. The passivation layer PSV may cover the entire lower end 150S1 of the at least one first alignment structure 150. The passivation layer PSV may protect the front pads 125 and the bump structures BP from external physical/chemical damage. The passivation layer PSV may include at least one of silicon oxide (SiO) or silicon nitride (SiN), but the present inventive concepts are not limited thereto. The passivation layer PSV may include a polymer such as photo solder resist (PSR).

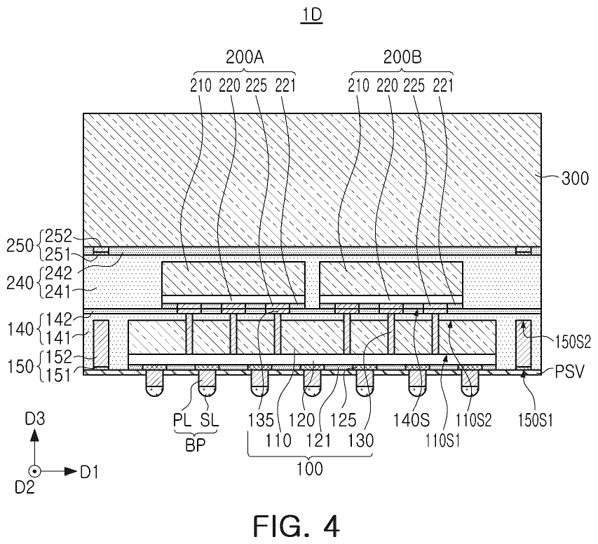

The second semiconductor chip 200 may be disposed on the first dielectric layer 140, and may include a second substrate 210, a second circuit layer 220, a second insulating layer 221, and connection pads 225. In some example embodiments, the second semiconductor chip 200 may be provided as a plurality of semiconductor chips vertically and/or horizontally disposed on the first semiconductor chip 100 (see the example embodiment of FIG. 4). The second semiconductor chip 200 may be disposed in a position, not overlapping the first alignment structure 150, but the present inventive concepts are not limited thereto.

The second semiconductor chip 200 may have components substantially the same as or similar to those of the first semiconductor chip 100, and thus the same or similar components are indicated by the same or similar reference numerals. Hereinafter, a repeated description of the same or similar components are omitted. For example, the second substrate 210 and the second circuit layer 220 have features the same as or similar to those of the first substrate 110 and the first circuit layer 120 described above, and thus repeated descriptions are omitted.

The second insulating layer 221 may be formed to surround the connection pads 225. The second insulating layer 221 may provide a bonding surface for bonding and coupling to the first dielectric layer 140. The second insulating layer 221 may include a material, for example, silicon oxide (SiO) or silicon carbonitride (SiCN), that may be bonded and coupled to the first dielectric layer 140 (or the first upper dielectric layer 142).

The connection pads 225 may be connection terminals electrically connected to an integrated circuit of the second circuit layer 220. The connection pads 225 may be connection terminals of a bare chip (e.g., aluminum pads), but the present inventive concepts are not limited thereto. In some example embodiments, the connection pads 225 may be connection structures (e.g., copper pads) formed on the connection terminals of the bare chip. The connection pads 225 may include a barrier layer (not illustrated), including at least one of titanium (Ti), titanium nitride (TiN), tantalum (Ta), or tantalum nitride (TaN), and disposed between the second insulating layers 221.

The second dielectric layer 240 may cover at least a portion of the second semiconductor chip 200. The second dielectric layer 240 may include a second lower dielectric layer 241 and a second upper dielectric layer 242. The second lower dielectric layer 241 may cover an upper surface and a side surface of the second semiconductor chip 200. In some example embodiments, the upper surface of the second semiconductor chip 200 may be exposed from the second lower dielectric layer 241. The second upper dielectric layer 242 may surround a side surface of at least one second alignment structure 250.

The second dielectric layer 240 may provide a bonding surface for bonding and coupling to the first dielectric layer 140. The second dielectric layer 240 may include at least one of silicon oxide (SiO), silicon nitride (SiN), or silicon carbonitride (SiCN). The second lower dielectric layer 241 may include a material, for example, silicon oxide (SiO) or silicon carbonitride (SiCN), that may be bonded and coupled to the first dielectric layer 140. The second upper dielectric layer 242 may include a material, for example, silicon oxide (SiO) or silicon carbonitride (SiCN), that may be bonded and coupled to a dummy chip 300. However, the material included in the second dielectric layer 240 is not limited to the examples described above.

In some example embodiments, the semiconductor package 1A may further include the at least one second alignment structure 250 and the dummy chip 300. The at least one second alignment structure 150 may be an alignment key for the dummy chip 300, and may be electrically insulated from the first semiconductor chip 100, the second semiconductor chip 200, and the dummy chip 300.

The second alignment structure 250 may be disposed within the second dielectric layer 240 around the second semiconductor chip 200. The at least one second alignment structure 250 may be disposed on at least one side of the second semiconductor chip 200. The second alignment structure 250 may at least partially overlap the first alignment structure 150 in a vertical direction D3, but the present inventive concepts are not limited thereto.

The second alignment structure 250 may include a second lower material layer 251 and a second upper material layer 252 on the second lower material layer 251. The second lower material layer 251 may include titanium (Ti) or a titanium (Ti) alloy, and the second upper material layer 252 may include copper (Cu) or a copper (Cu) alloy. However, a constituent material of the second alignment structure 250 are not limited to the metal described above, and the second alignment structure 250 may include a material that may be detected by an alignment key in the process of disposing the dummy chip 300, without limitation. Depending on the process, the second lower material layer 251 may extend to a side surface of the second upper material layer 252.

The second alignment structure 250 may have a height lower than that of the first alignment structure 150. A height 150H of the at least one first alignment structure 150 may be higher than a height of the at least one second alignment structure 250.

The dummy chip 300 may be disposed on the second dielectric layer 240. The dummy chip 300 may be electrically insulated from the first semiconductor chip 100 and the second semiconductor chip 200. The dummy chip 300 may be attached to handle lower structures during a process of manufacturing the semiconductor package 1A and to adjust an overall thickness of the semiconductor package 1A. The dummy chip 300 may be a silicon wafer ground to a desired or required thickness.

FIG. 2 is a cross-sectional view of a semiconductor package 1B according to an example embodiment.

Referring to FIG. 2, the semiconductor package 1B according to the example embodiment may have features the same as or similar to those described with reference to FIGS. 1A and 1B, except that a first alignment structure 150 extends to an upper surface 141S of a first lower dielectric layer 141.

The first alignment structure 150 may be formed to have a height passing through the entire first lower dielectric layer 141. A lower end 150S1 of the first alignment structure 150 may be coplanar with a lower surface of each of front pads 125 and a lower surface of the first lower dielectric layer 141. An upper end 150S2 of the first alignment structure 150 may be coplanar with the upper surface 141S of the first lower dielectric layer 141 and an upper end of each of through-electrodes 130. The upper end 150S2 of the first alignment structure 150, the upper surface 141S of the first lower dielectric layer 141, and the upper end of each of the through-electrodes 130 may be planarized using the same CMP process.

FIG. 3 is a cross-sectional view of a semiconductor package 1C according to an example embodiment.

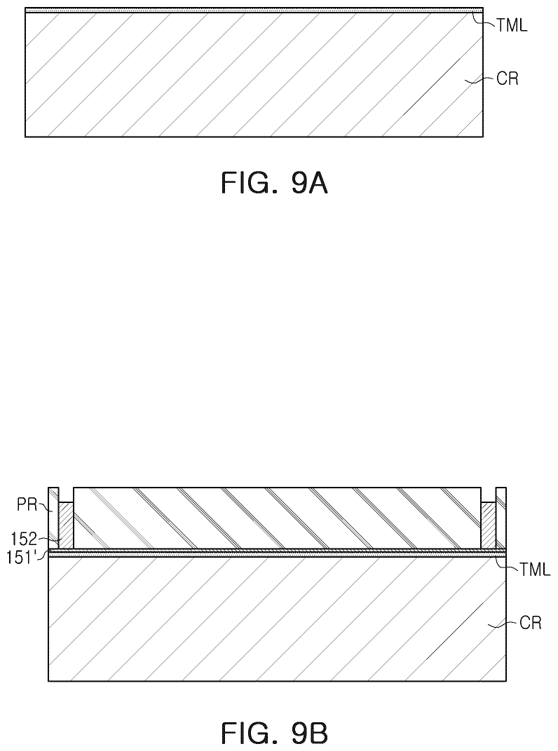

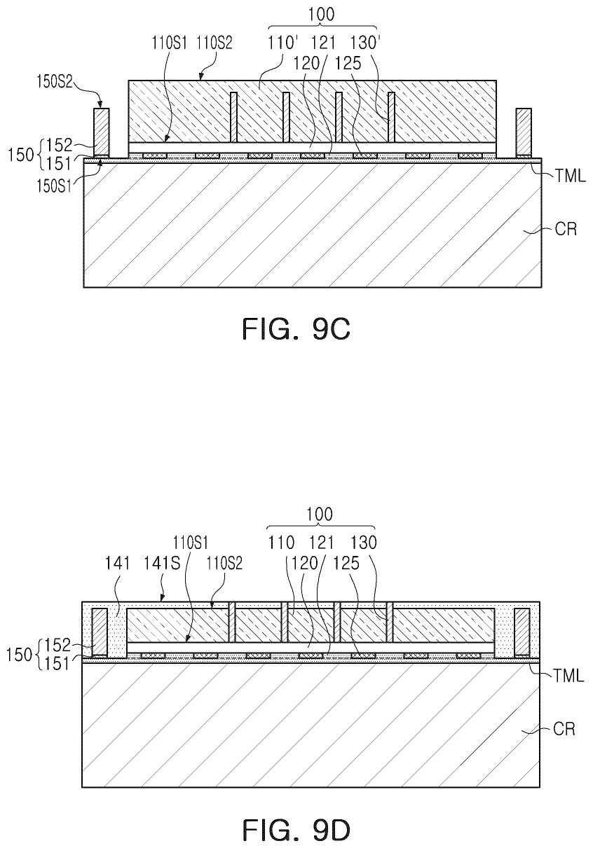

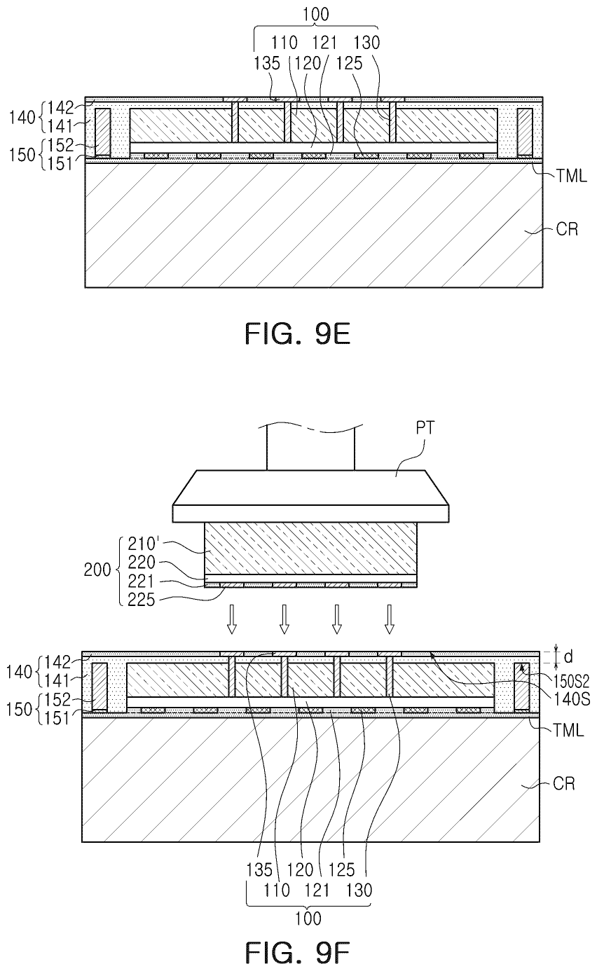

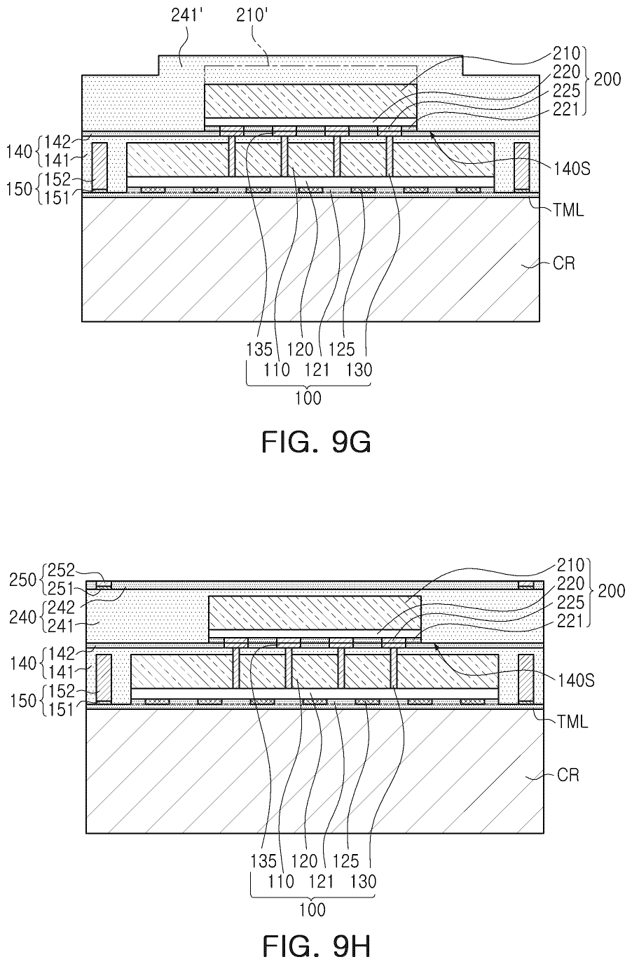

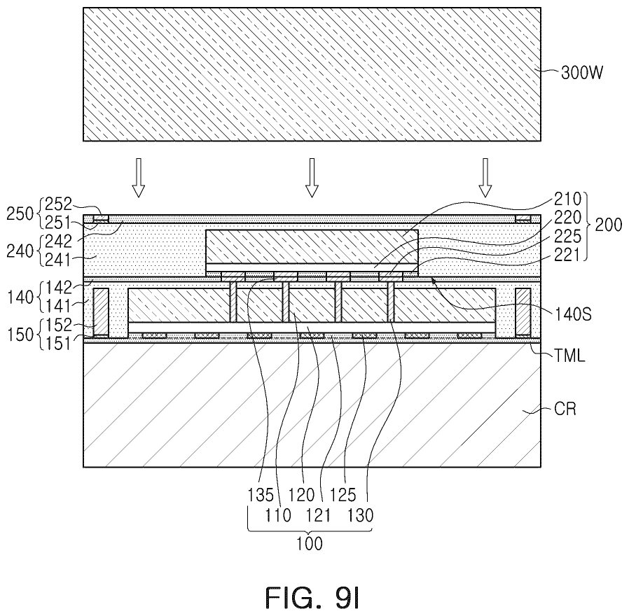

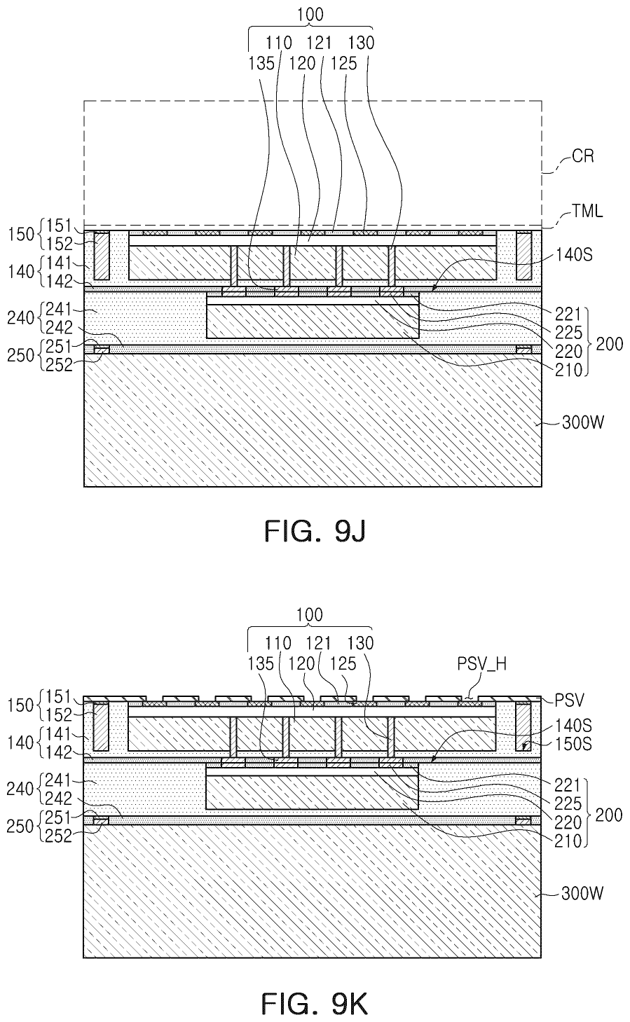

Referring to FIG. 3, the semiconductor package 1C according to an example embodiment may have features the same as or similar to those described with reference to FIGS. 1A to 2, except that a passivation layer PSV is a remaining portion of a temporary bonding layer (“TML” in FIG. 9A).

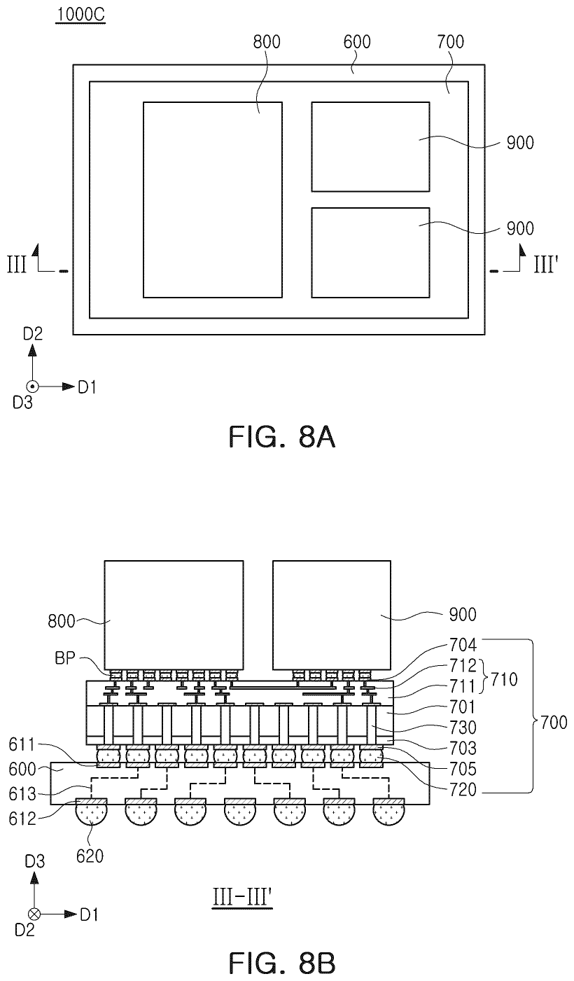

The passivation layer PSV may be a portion of the temporary bonding layer (“TML” in FIG. 8A) used in a process of manufacturing the semiconductor package 1C. The passivation layer PSV may include a material, for example, silicon oxide (SiO) or silicon carbonitride (SiCN), that may be bonded and coupled to a first insulating layer 121. Depending on a material and/or process of the passivation layer PSV, a boundary between the passivation layer PSV and the first insulating layer 121 may not be clearly identified.

FIG. 4 is a cross-sectional view of a semiconductor package 1D according to an example embodiment.

Referring to FIG. 4, the semiconductor package 1D according to an example embodiment may have features the same as or similar to those described with reference to FIGS. 1A to 3, except that a plurality of second semiconductor chips 200A and 200B are included.

Each of the plurality of second semiconductor chips 200A and 200B may include a second substrate 210, a second circuit layer 220, a second insulating layer 221, and connection pads 225. The plurality of second semiconductor chips 200A and 200B may be provided as two or more semiconductor chips horizontally disposed on a first dielectric layer 140. In some example embodiments, the plurality of second semiconductor chips 200A and 200B may be stacked on the first dielectric layer 140 in a vertical direction D3. In this case, some semiconductor chips, among the plurality of second semiconductor chips 200A and 200B, may include through-electrodes, passing through the second substrate 210.

In some example embodiments, a first semiconductor chip 100A and the plurality of second semiconductor chips 200A and 200B may be chiplets included in a multi-chip module (MCM). For example, the first semiconductor chip 100A may include a processor circuit, and the plurality of second semiconductor chips 200A and 200B may include input/output circuits, analog circuits, memory circuits, and serial-to-parallel conversion circuits for the first semiconductor chip 100A.

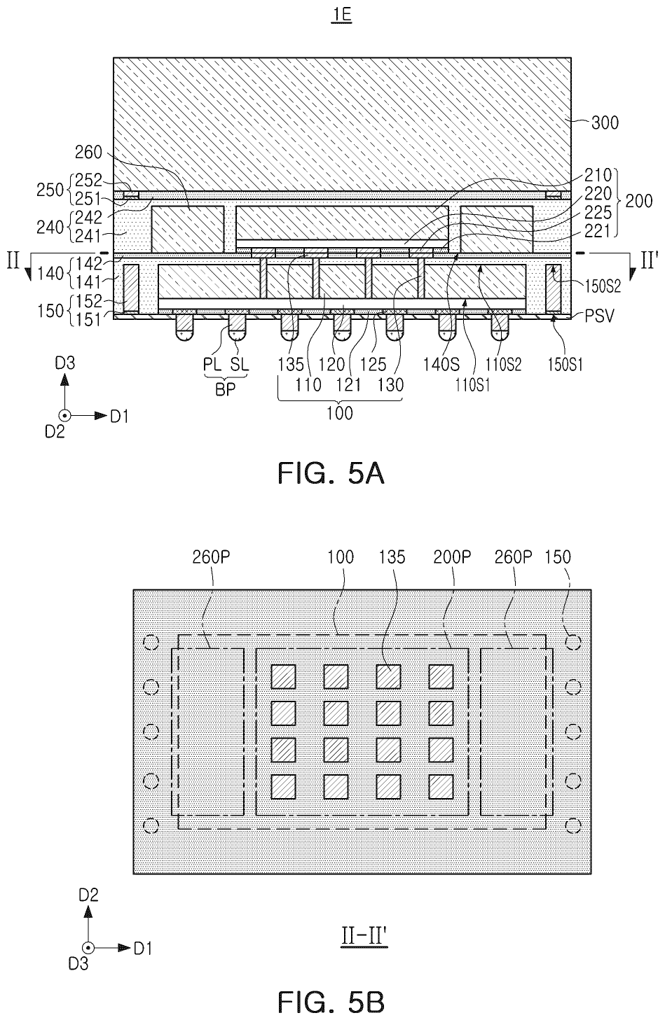

FIG. 5A is a cross-sectional view of a semiconductor package 1E according to an example embodiment, and FIG. 5B is a plan view taken along line II-II′ of FIG. 5A.

Referring to FIGS. 5A and 5B, the semiconductor package 1E according to an example embodiment may have features the same as or similar to those described with reference to FIGS. 1A to 4, except that at least one dummy structure 260 is included.

The at least one dummy structure 260 may be disposed within a second dielectric layer 240 around a second semiconductor chip 200. The dummy structure 260 may be disposed on a level the same as that of the second semiconductor chip 200. A lower surface of the dummy structure 260 may be in contact with an upper surface 140S of a first dielectric layer 140. The lower surface of the dummy structure 260 may be coplanar with a lower surface of the second semiconductor chip 200. The dummy structure 260 may be a silicon dummy buried within the second dielectric layer 240.

A first alignment structure 150 may be used as an alignment key to determine a position 200P in which the second semiconductor chip 200 is attached and a position 260P in which the dummy structure 260 is attached.

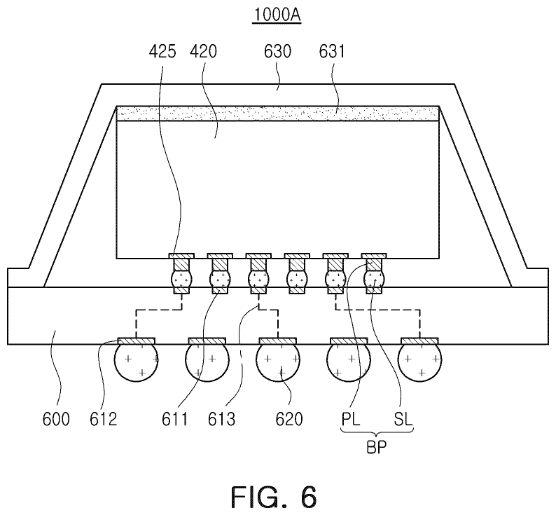

FIG. 6 is a cross-sectional view of a semiconductor package 1000A according to an example embodiment.

Referring to FIG. 6, the semiconductor package 1000A according to an example embodiment may include a semiconductor chip structure 420, a package substrate 600, and a thermal dissipation structure 630. The semiconductor chip structure 420 may be a semiconductor package structure having features the same as or similar to those of the semiconductor packages 1A, 1B, 1C, 1D, and 1E described with reference to FIGS. 1A to 5. The semiconductor chip structure 420 may be electrically connected to the package substrate 600 via a bump structure BP on a connection terminal 425.

The package substrate 600 may be a support substrate on which the semiconductor chip structure 420 is mounted, and may be a substrate for a semiconductor package, such as a printed circuit board (PCB), a ceramic substrate, or a tape interconnection board. The package substrate 600 may include a lower pad 612, an upper pad 611, and an interconnection circuit 613 electrically connecting the lower pad 612 and the upper pad 611 to each other. A body of the package substrate 600 may include a material varying depending on a type of substrate. For example, when the package substrate 600 is a printed circuit board, the package substrate 600 may be in the form of a body copper clad laminate or an interconnection layer additionally laminated on one surface or both surfaces of a copper clad laminate. The upper pad 611, the lower pad 612, and a redistribution circuit 613 may form an electrical path connecting a lower surface and an upper surface of the package substrate 600 to each other. An external connection bump 620 may be disposed on the lower pad 612. The external connection bump 620 may include tin (Sn), indium (In), bismuth (Bi), antimony (Sb), copper (Cu), silver (Ag), zinc (Zn), lead (Pb), and/or alloys thereof.

The thermal dissipation structure 630 may be disposed to cover an upper portion of the semiconductor chip structure 420. The thermal dissipation structure 630 may be attached to the package substrate 600 using an adhesive (not illustrated). The thermal dissipation structure 630 may include a material having excellent thermal conductivity, for example, aluminum (Al), gold (Au), silver (Ag), copper (Cu), iron (Fe), graphite, or graphene. The thermal dissipation structure 630 may have a shape different from that illustrated in the drawing. For example, the thermal dissipation structure 630 may be formed to cover only an upper surface of the semiconductor chip structure 420. The thermal dissipation structure 630 may be attached to the upper portion of the semiconductor chip structure 420 via a heat transfer material layer 631. The heat transfer material layer 631 may include a thermal interface material (TIM), such as a thermally conductive adhesive tape, thermally conductive grease, or thermally conductive adhesive.

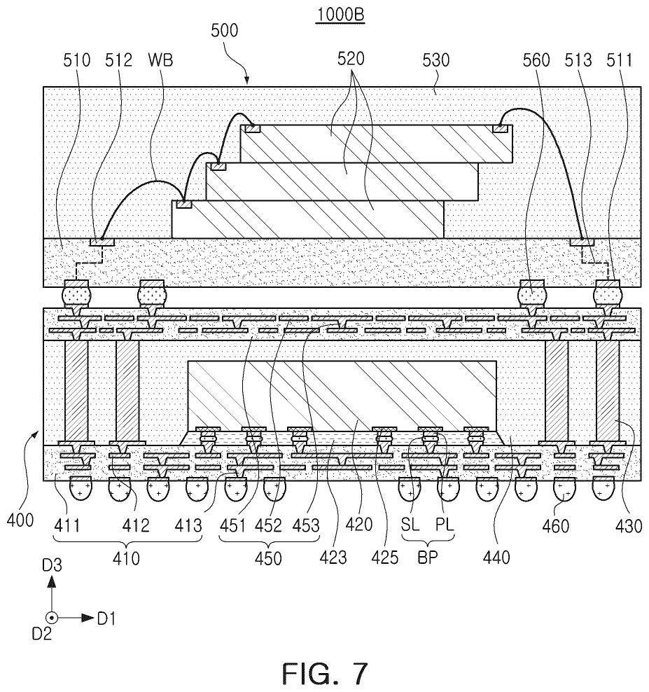

FIG. 7 is a cross-sectional view of a semiconductor package 1000B according to an example embodiment.

Referring to FIG. 7, the semiconductor package 1000B according to an example embodiment may include a first package 400 and a second package 500.

The first package 400 may include a lower redistribution structure 410, a first semiconductor chip structure 420, a through-via 430, a first mold layer 440, an upper redistribution structure 450, and first connection bumps 460.

The lower redistribution structure 410 may include a lower insulating layer 411, lower redistribution layers 412, and lower vias 413.

The lower insulating layer 411 may include a thermosetting resin such as an epoxy resin, a thermoplastic resin such as polyimide, or a resin in which an inorganic filler is impregnated into the resins (e.g., prepreg, an Ajinomoto build-up film (ABF), FR-4, BT, or the like). In some example embodiments, the lower insulating layer 411 may include a photosensitive resin such as a photo-imageable dielectric (PID).

The lower redistribution layers 412 and the lower vias 413 may include a metal material including copper (Cu), aluminum (Al), silver (Ag), tin (Sn), gold (Au), nickel (Ni), lead (Pb), titanium (Ti) or alloys thereof.

The lower vias 413 may interconnect the lower redistribution layers 412 on different levels. The lower vias 413 may be filled-vias in which a via hole is filled with a metal material, or conformal vias in which a metal material extends along an inner wall of a via hole.

The first semiconductor chip structure 420 may be a semiconductor package structure having features the same as or similar to those of the semiconductor packages 1A, 1B, 1C, 1D, and 1E described with reference to FIGS. 1A to 5. The first semiconductor chip structure 420 may be electrically connected to a package substrate 600 via a bump structure BP on a connection terminal 425. An underfill layer 423 may be disposed between the first semiconductor chip structure 420 and the lower redistribution structure 410. The underfill layer 423 may include an insulating resin such as an epoxy resin, and may physically and electrically protect the connection bumps 460. The underfill layer 423 may have a capillary underfill (CUF) structure, but the present inventive concepts are not limited thereto. In some example embodiments, the underfill layer 423 may have a molded underfill (MUF) structure integrated with the mold layer 440.

The through-via 430 may pass through the mold layer 440, and may electrically connect the lower redistribution layers 412 and the upper redistribution layers 452 to each other. The through-via 430 may have a post shape, passing through the mold layer 440. The through-via 430 may include a metal material including copper (Cu), aluminum (Al), silver (Ag), tin (Sn), gold (Au), nickel (Ni), lead (Pb), titanium (Ti), or alloys thereof.

The first mold layer 440 may include, for example, a thermosetting resin such as an epoxy resin, a thermoplastic resin such as polyimide, or prepreg, an ABF, FR-4, BT, or an epoxy molding compound (EMC) in which an inorganic filler is impregnated into the resins.

The upper redistribution structure 450 may include an upper insulating layer 451, upper redistribution layers 452, and upper vias 453. The upper insulating layer 451, the upper redistribution layers 452, and the upper vias 453 may have features the same as or similar to those of the lower insulating layer 411, the lower redistribution layers 412, and the lower vias 413 described above, and thus repeated descriptions are omitted.

The first connection bumps 460 may be disposed below the lower redistribution structure 410. The first package 400 may be connected to an external device such as a module substrate or a system board via the first connection bumps 460. The first connection bumps 460 may include a low melting point metal, for example, tin (Sn) or an alloy including tin (Sn) (e.g., Sn—Ag—Cu).

The second package 500 may include an interconnection board 510, a second semiconductor chip structure 520, and a second mold layer 530. The interconnection board 510 may include a lower pad 511, an upper pad 512, and an interconnection circuit 513.

The second semiconductor chip structure 520 may be mounted on the interconnection board 510 in a wire bonding manner or a flip chip bonding manner. For example, the second semiconductor chip structure 520 may include a plurality of semiconductor chips stacked in a vertical direction, and may be electrically connected to the upper pad 512 of the interconnection board 510 via a bonding wire WB. The second semiconductor chip structure 520 may include a different type of semiconductor chip from that of the first semiconductor chip structure 420. For example, the second semiconductor chip structure 520 may include a plurality of memory chips, and the first semiconductor chip structure 420 may include an application processor (AP) chip.

The second mold layer 530 may include a material the same as or similar to that of the first mold layer 440 of the first package 400. The second package 500 may be physically and electrically connected to the first package 400 by a second connection bump 560. The second connection bump 560 may include a material the same as or similar to that of the first connection bump 460.

FIG. 8A is a plan view of a semiconductor package 1000C according to an example embodiment, and FIG. 8B is a cross-sectional view taken along line III-III′ of FIG. 8A.

Referring to FIGS. 8A and 8B, the semiconductor package 1000C according to an example embodiment may include a package substrate 600, an interposer substrate 700, a first semiconductor chip structure 800, and a second semiconductor chip structure 900. The package substrate 600 may have features the same as or similar to those of those described with reference to FIG. 6, and thus repeated descriptions are omitted.

The first semiconductor chip structure 800 may be a semiconductor package structure having features the same as or similar to those of the semiconductor packages 1A, 1B, 1C, 1D, and 1E described with reference to FIGS. 1A to 5.

The second semiconductor chip structure 900 may include a different type of semiconductor chip from that of the first semiconductor chip structure 800. For example, the second semiconductor chip structure 900 may include a plurality of memory chips, and the first semiconductor chip structure 800 may include a logic chip such as a CPU, a GPU, or an ASIC. In this case, the second semiconductor chip structure 900 may be provided as a high-capacity memory device such as high bandwidth memory (HBM).

The interposer substrate 700 may include a semiconductor substrate 701, a lower protective layer 703, a lower pad 705, an interconnection structure 710, a conductive bump 720, and a through-via 730. The first semiconductor chip structure 800 and the second semiconductor chip structure 900 may be electrically connected to each other via the interposer substrate 700.

The semiconductor substrate 701 may be formed of, for example, one of silicon, organic, plastic, and glass substrates. When the semiconductor substrate 701 is a silicon substrate, the interposer substrate 700 may be referred to as a silicon interposer. Unlike that illustrated in the drawing, when the semiconductor substrate 701 is an organic substrate, the interposer substrate 700 may be referred to as a panel interposer.

The lower protective layer 703 may be disposed on a lower surface of the semiconductor substrate 701, and the lower pad 705 may be disposed below the lower protective layer 703. The lower pad 705 may be connected to the through-via 730. The first semiconductor chip structure 800 and the second semiconductor chip structure 900 may be electrically connected to the package substrate 600 via conductive bumps 720 disposed below the lower pad 705.

The interconnection structure 710 may be disposed on an upper surface of the semiconductor substrate 701, and may include an interlayer insulating layer 711 and a single-layer or multilayer interconnections 712. When the interconnection structure 710 has a multilayer interconnections, interconnection patterns of different layers may be connected to each other by an interconnection via.

The through-via 730 may extend from an upper surface to a lower surface of the semiconductor substrate 701, and may pass through the semiconductor substrate 701. In addition, the through-via 730 may extend into the interconnection structure 710, and may be electrically connected to interconnections of the interconnection structure 710. When the semiconductor substrate 701 is a silicon substrate, the through-via 730 may be referred to as a TSV. In some example embodiments, the interposer substrate 700 may include only an interconnection structure therein, and may not include a through-via.

The interposer substrate 700 may be used to convert or transmit an input electrical signal between the package substrate 600 and the first semiconductor chip structure 800 or the second semiconductor chip structure 900. Accordingly, the interposer substrate 700 may not include devices such as active devices or passive devices. In addition, in some example embodiments, the interconnection structure 710 may be disposed on a lower portion of the through-via 730. For example, the interconnection structure 710 and the through-via 730 may have a relative positional relationship therebetween.

The conductive bump 720 may electrically connect the interposer substrate 700 and the package substrate 600 to each other. The first semiconductor chip structure 800 and the second semiconductor chip structure 900 may be electrically connected to the conductive bump 720 via the interconnections of the interconnection structure 710 and the through-via 730.

In some example embodiments, the semiconductor package 1000C may further include an internal mold layer (not illustrated) covering the first semiconductor chip structure 800 and the second semiconductor chip structure 900 on the interposer substrate 700. In addition, the semiconductor package 1000C may further include an external mold layer (not illustrated) covering the interposer substrate 700 and the internal mold layer (not illustrated), on the package substrate 600. The external mold layer (not illustrated) and the internal mold layer (not illustrated) may be formed together, and thus may not be distinguished from each other. In some example embodiments, the semiconductor package 1000C may further include a thermal dissipation structure covering the first semiconductor chip structure 800 and the second semiconductor chip structure 900.

FIGS. 9A to 9K are diagrams illustrating a process of manufacturing a semiconductor package according to an example embodiment. FIGS. 9A to 9K sequentially illustrate processes of manufacturing the semiconductor package 1A illustrated in FIGS. 1A and 1B.

Referring to FIG. 9A, a temporary bonding layer TML may be formed on a recombination carrier CR. In order to illustrate a process of manufacturing the semiconductor packages 1A illustrated in FIG. 1A, only one unit of the recombination carrier CR is illustrated. That is, the recombination carrier CR may be a 6-inch, 8-inch, or 12-inch silicon wafer including dozens or more of one units illustrated in the drawing. Hereinafter, for ease of description, a process of manufacturing a semiconductor package will be described based on the one unit illustrated in the drawing. The temporary bonding layer TML may include silicon oxide (SiO). The temporary bonding layer TML may be formed using a PVD or CVD process.

Referring to FIG. 9B, a seed layer 151′ and a plating layer 152 may be formed on the temporary bonding layer TML. The seed layer 151′ may include metal such as titanium (Ti), and may be formed using, for example, a PVD process. The plating layer 152 may include metal such as copper (Cu), and may be formed using a plating process using the seed layer 151′. The plating layer 152 may have a post shape having a desired (or alternatively, predetermined) height using a patterned photosensitive material layer PR. The plating layer 152 may be understood as a component corresponding to the “first upper material layer 152” of the above-described first alignment structure 150. Thereafter, an ashing process may be performed to remove the photosensitive material layer PR and to partially etch the seed layer 151′. The seed layer 151′ may be understood as a component corresponding to the “first lower material layer 151” of the above-described first alignment structure 150.

Referring to FIG. 9C, a first semiconductor chip 100 may be attached to the temporary bonding layer TML. The first semiconductor chip 100 may include a first preliminary substrate 110′, a first circuit layer 120, preliminary through-electrodes 130′, front pads 125, and a first insulating layer 121. The first semiconductor chip 100 may be a known good die (KGD) for which testing is completed. The first semiconductor chip 100 may be attached to a position determined using the first alignment structure 150 as an alignment key. The first preliminary substrate 110′ may be a silicon die having a thickness that has not been adjusted using a back-grinding process. The first semiconductor chip 100 may be attached to the temporary bonding layer TML using a thermal compression process. The thermal compression process may be performed in a thermal atmosphere ranging from about 100° C. to about 300° C. However, a temperature of the thermal atmosphere is not limited to the above-described range and may vary. The first insulating layer 121 and the temporary bonding layer TML may not be clearly distinguished from each other.

Thereafter, a back-grinding process and an etch-back process may be applied to the first preliminary substrate 110′, such that the thickness of the first preliminary substrate 110′ may be reduced, and the preliminary through-electrodes 130′ may protrude to a rear surface 110S2.

Referring to FIG. 9D, a first lower dielectric layer 141 may be formed. The first lower dielectric layer 141 may cover the first alignment structures 150 and the first semiconductor chip 100. The first lower dielectric layer 141 around the first semiconductor chip 100 may have improved filling characteristics by the first alignment structures 150. Accordingly, the first lower dielectric layer 141 may have a relatively low thickness, thereby improving the efficiency of a subsequent planarization process. A CMP process may be applied to the first lower dielectric layer 141, such that through-electrodes 130 may be exposed to an upper surface 141S of the first lower dielectric layer 141. The first lower dielectric layer 141 may surround a side surface of each of the through-electrodes 130 protruding to a rear surface 110S2 of a first substrate 110. The first lower dielectric layer 141 may cover the entire upper ends of the first alignment structures 150. The first lower dielectric layer 141 may include silicon oxide (SiO), and may be formed using a PVD or CVD process.

Referring to FIG. 9E, a first upper dielectric layer 142 and rear pads 135 may be formed on the first lower dielectric layer 141. The first upper dielectric layer 142 may include silicon oxide (SiO), and may be formed using a PVD or CVD process. The rear pads 135 may be formed within a photosensitive material layer (not shown) and the first upper dielectric layer 142 patterned using a photolithography process. The rear pads 135 may include metal such as copper (Cu) or titanium (Ti), and may be formed using a plating process. The first upper dielectric layer 142 and the rear pads 135 may be planarized using a CMP process.

Referring to FIG. 9F, a second semiconductor chip 200 may be attached to the first semiconductor chip 100. The second semiconductor chip 200 may be disposed on the first semiconductor chip 100 and the first dielectric layer 140 by a pick-and-place device PT. The second semiconductor chip 200 may include a second preliminary substrate 210′, a second circuit layer 220, connection pads 225, and a second insulating layer 221. The second semiconductor chip 200 may be a KGD for which testing has been completed. The second semiconductor chip 200 may be attached to a position determined using the first alignment structure 150 as an alignment key. A gap d between an upper surface 140S of the first dielectric layer 140 and an upper end 150S2 of the first alignment structure 150 may range from about 4 μm to about 10 μm.

The second preliminary substrate 210′ may be a silicon die having a thickness that has not been adjusted using a back-grinding process. The second semiconductor chip 200 may be attached to the first dielectric layer 140 and the first semiconductor chip 100 using a thermal compression process. The connection pads 225 may include metal (e.g., copper (Cu)) that may be bonded and coupled to the rear pads 135. The second insulating layer 221 may include an insulating material (e.g., silicon oxide (SiO)) that may be bonded and coupled to the first upper dielectric layer 142. A bonding surface between the second insulating layer 221 and the first upper dielectric layer 142 may not be clearly identified.

Referring to FIG. 9G, a preliminary dielectric layer 241′ may be formed. The preliminary dielectric layer 241′ may be formed to cover a second substrate 210 having a thickness that has been reduced by applying a back-grinding process to the second preliminary substrate 210′. The preliminary dielectric layer 241′ may include silicon oxide (SiO), and may be formed using a PVD or CVD process. A second lower dielectric layer 241 having a flat upper surface may be formed by applying a CMP process to the preliminary dielectric layer 241′.

Referring to FIG. 9H, a second upper dielectric layer 242 and second alignment structures 250 may be formed on the second lower dielectric layer 241. The second upper dielectric layer 242 may include silicon oxide (SiO), and may be formed using a PVD or CVD process. The second alignment structures 250 may include metal such as copper (Cu) or titanium (Ti), and may be formed using a plating process. The second upper dielectric layer 242 and the second alignment structures 250 may be planarized using a CMP process. The second alignment structures 250 may include a second lower material layer 251 and a second upper material layer 252 on the second lower material layer 251. The second lower material layer 251 may include titanium (Ti), and the second upper material layer 252 may include copper (Cu). Depending on the process, the second lower material layer 251 may extend to a side surface of the second upper material layer 252.

Referring to FIG. 9I, a dummy wafer 300W may be attached to the second semiconductor chip 200. The dummy wafer 300W may be a silicon wafer having a size corresponding to that of the recombination carrier CR, for example, 6 inches, 8 inches, or 12 inches. The dummy wafer 300W may be attached in a state in which the dummy wafer 300w has a thickness that has been adjusted using a grinding process, or may be attached to the second semiconductor chip 200 and then subjected to a grinding process. The dummy wafer 300W may be attached to a position determined using the second alignment structure 250 as an alignment key.

Referring to FIG. 9J, the recombination carrier CR and the temporary bonding layer TML may be removed. The recombination carrier CR and the temporary bonding layer TML may be removed using a combination of a grinding process and an etching process. The temporary bonding layer TML may be entirely removed, such that front pads 125 and the first alignment structures 150 of the first semiconductor chip 100 may be exposed. In some example embodiments, a portion of the temporary bonding layer TML may remain and serve as a passivation layer covering the front pads 125 and the first alignment structures 150.

Referring to FIG. 9K, a passivation layer PSV may be formed on the front pads 125 and the first alignment structures 150. The passivation layer PSV may have openings PSV_H exposing at least a portion of each of the front pads 125. The openings PSV_H may be formed in a position determined using the first alignment structure 150 as an alignment key. Thereafter, bump structures may be formed in the openings PSV_H and then a dicing process may be performed to separate unit packages from each other.

As such, according to example embodiments, the first alignment structure 150 may be used as an alignment key for arrangement of the first semiconductor chip 100, arrangement of the second semiconductor chip 200, and patterning of the passivation layer PSV, thereby providing a semiconductor package with a simplified process and improved yield.

According to some example embodiments of the present inventive concepts, an alignment key having a post shape may be introduced, thereby simplifying a process of a semiconductor package.

While some example embodiments have been shown and described above, it will be apparent to those skilled in the art that modifications and variations could be made without departing from the scope of the present inventive concepts as defined by the appended claims.

What is claimed is:

1. A semiconductor package comprising:
a first semiconductor chip including a substrate having a front surface and a rear surface opposite to each other, front pads on the front surface, through-electrodes electrically connected to the front pads, passing through the substrate, and protruding onto the rear surface, and rear pads on the through-electrodes;
a first dielectric layer covering at least a portion of the first semiconductor chip, the first dielectric layer surrounding, on the rear surface of the substrate, a portion of a side surface of each of the through-electrodes and a side surface of each of the rear pads, on the rear surface of the substrate;
at least one first alignment structure within the first dielectric layer and around the first semiconductor chip;
a second semiconductor chip on the first dielectric layer, the second semiconductor chip including connection pads in contact with the rear pads, and an insulating layer surrounding the connection pads and being in contact with the first dielectric layer;
a second dielectric layer covering at least a portion of the second semiconductor chip, the second dielectric layer in contact with the first dielectric layer;
at least one second alignment structure within the second dielectric layer around the second semiconductor chip;
a dummy chip on the second dielectric layer; and
bump structures on the front pads of the first semiconductor chip.

2. The semiconductor package of claim 1, wherein a height of the at least one first alignment structure is greater than a thickness of the substrate.

3. The semiconductor package of claim 1, wherein an upper end of the at least one first alignment structure is on a level between the rear surface of the substrate and an upper surface of the first dielectric layer.

4. The semiconductor package of claim 3, wherein a gap between the upper end of the at least one first alignment structure and the upper surface of the first dielectric layer ranges from about 4 μm to about 10 μm.

5. The semiconductor package of claim 1, wherein
the first dielectric layer includes a first lower dielectric layer and a first upper dielectric layer on the first lower dielectric layer,
the first lower dielectric layer surrounds a side surface of the first semiconductor chip, a side surface of the at least one first alignment structure, and the portion of the side surface of each of the through-electrodes, and
the first upper dielectric layer surrounds the side surface of each of the rear pads.

6. The semiconductor package of claim 5, wherein an upper end of the at least one first alignment structure is on a level the same as or lower than that of an upper surface of the first lower dielectric layer.

7. The semiconductor package of claim 5, wherein the first upper dielectric layer and the insulating layer of the second semiconductor chip include at least one of silicon oxide (SiO), silicon nitride (SiN), or silicon carbonitride (SiCN).

8. The semiconductor package of claim 1, wherein a lower end of the at least one first alignment structure is coplanar with a lower surface of the first dielectric layer.

9. The semiconductor package of claim 1, wherein
the at least one first alignment structure includes a lower material layer and an upper material layer on the lower material layer,
the lower material layer includes titanium (Ti) or a titanium (Ti) alloy, and
the upper material layer includes copper (Cu) or a copper (Cu) alloy.

10. The semiconductor package of claim 1, wherein a height of the at least one first alignment structure is greater than a height of the at least one second alignment structure.

11. The semiconductor package of claim 1, wherein
the second dielectric layer includes a second lower dielectric layer and a second upper dielectric layer on the second lower dielectric layer,
the second lower dielectric layer surrounds a side surface of the second semiconductor chip, and
the second upper dielectric layer surrounds a side surface of the at least one second alignment structure.

12. The semiconductor package of claim 1, further comprising:
a passivation layer below the first dielectric layer, the passivation layer covering a bottom of the at least one first alignment structure and surrounding each of the bump structures.

13. The semiconductor package of claim 12, wherein the passivation layer includes at least one of silicon oxide (SiO) or silicon nitride (SiN).

14. The semiconductor package of claim 1, wherein a planar area of the second semiconductor chip is smaller than a planar area of the first semiconductor chip.

15. The semiconductor package of claim 1, further comprising:
at least one dummy structure within the second dielectric layer and around the second semiconductor chip.

16. A semiconductor package comprising:
a first semiconductor chip including front pads, rear pads opposite to the front pads, and through-electrodes electrically connecting the front pads and the rear pads to each other;
at least one alignment structure around the first semiconductor chip;
a lower dielectric layer surrounding a side surface of the at least one alignment structure and a side surface of the first semiconductor chip;
an upper dielectric layer on the lower dielectric layer and surrounding a side surface of each of the rear pads; and
a second semiconductor chip on the upper dielectric layer, the second semiconductor chip including connection pads in contact with the rear pads, and an insulating layer surrounding the connection pads and being in contact with the upper dielectric layer.

17. The semiconductor package of claim 16, wherein an upper end of the at least one alignment structure is on a level the same as or lower than that of an upper end of each of the through-electrodes.

18. The semiconductor package of claim 16, wherein the lower dielectric layer or the upper dielectric layer covers an entire upper end of the at least one alignment structure.

19. The semiconductor package of claim 16, wherein a lower end of the at least one alignment structure is on a level the same as that of each of the front pads of the first semiconductor chip.

20. A semiconductor package comprising:
a first semiconductor chip including a substrate having a front surface and a rear surface opposite to each other, front pads on the front surface, through-electrodes electrically connected to the front pads and extending onto the rear surface, and rear pads on the through-electrodes;
at least one alignment structure around the first semiconductor chip;
a first dielectric layer covering the rear surface and a side surface of the substrate, a portion of a side surface of each of the through-electrodes, a side surface of each of the rear pads, and a side surface and an upper end of the at least one alignment structure;
a second semiconductor chip on the first dielectric layer, the second semiconductor chip including connection pads in contact with the rear pads, and an insulating layer surrounding the connection pads and being in contact with the first dielectric layer;
a second dielectric layer covering an upper surface and a side surface of the second semiconductor chip; and
a dummy chip on the second dielectric layer,
wherein the at least one alignment structure is electrically insulated from the first semiconductor chip, the second semiconductor chip, and the dummy chip.
